(19) United States
(12) Patent Application Publication
(10) Pub. No.: US 2012/0211075 A1
(43) Pub. Date: Aug. 23, 2012

(54) ORGANIC PHOTOVOLTAIC CELL AND METHOD FOR MANUFACTURING THEREOF

(76) Inventors: Takahiro Seike, Ibaraki (JP); Toshihiro Ohnishi, Ibaraki (JP)

(21) Appl. No.: 13/502,577

(22) PCT Filed: Oct. 25, 2010
(86) PCT No.: PCT/JP2010/068878

§ 371 Date: Apr. 18, 2012

(30) Foreign Application Priority Data
Oct. 29, 2009 (JP) 2009-249515

(51) Int. Cl. H01L 31/0224; B82Y 99/00

(52) U.S. Cl. 136/256; 438/98; 257/E31.124; 977/948

(57) ABSTRACT

Provided is an organic photoelectric cell having excellent electrical characteristics. An organic photovoltaic cell (10) comprises: a pair of electrodes of a first electrode (32) and a second electrode (34); and an active layer (40) placed between the pair of electrodes, in which either one of the pair of electrodes comprises an alkali metal salt or an alkaline earth metal salt, and a conductive material.

### TECHNICAL FIELD

The present invention relates to an organic photovoltaic cell and a method for manufacturing thereof.

### BACKGROUND ART

An organic photovoltaic cell is usually manufactured by a method for manufacturing comprising the steps of: (1) preparing a substrate; (2) forming a first electrode on the substrate; (3) forming a first charge transport layer on the first electrode; (4) forming an active layer on the first charge transport layer; (5) forming a second charge transport layer on the active layer; and (6) forming a second electrode on the second charge transport layer.

Particularly, the active layer is vulnerable to high temperature because the active layer comprises organic compounds such as an electron acceptor compound and an electron donor compound. Therefore, the active layer may deteriorate its electrical characteristics or may lose functions due to decomposition of the organic compounds by a high temperature process in a successive charge transport layer forming step, such as a deposition process in a step of forming an electrode like an aluminum electrode.

Various studies have been performed for chemical deterioration and functional deterioration of a material for the organic photovoltaic cell comprising the active layer comprising organic compounds and an aluminum electrode provided on the active layer (Non Patent Document 1).

### RELATED ART DOCUMENTS

### Non Patent Document

Non Patent Document 1: Solar Energy Materials and Solar Cells., 92, (2008) 686

### DISCLOSURE OF INVENTION

However, in the case of an organic photovoltaic cell that requires the conventional film forming step at the high temperature, organic compounds comprised in a functional layer such as the active layer may be decomposed by heat. As a result, the organic photovoltaic cell may malfunction.

When a film is formed by deposition or the like, large-scale and expensive equipment such as a vacuum system is required. Therefore, the manufacturing step may be complicated and the manufacturing cost may increase.

The inventors of the present invention have eagerly investigated an organic photovoltaic cell and a method for manufacturing the same and have accomplished the present invention.

Namely, the present invention provides the following organic photovoltaic cell and the method for manufacturing the same.

[1] An organic photovoltaic cell comprising:
a pair of electrodes of a first electrode and a second electrode; and an active layer placed between the pair of electrodes, wherein
either one of the pair of electrodes comprises an alkali metal salt or an alkaline earth metal salt, and a conductive material.

[2] An organic photovoltaic cell comprising:
a pair of electrodes of a first electrode and a second electrode; and an active layer placed between the pair of electrodes, wherein
either one of the pair of electrodes is constituted by stacking a metal salt layer comprising an alkali metal salt or an alkaline earth metal salt and a conductive material layer comprising a conductive material; and
the metal salt layer is joined with the active layer.

[3] The organic photovoltaic cell according to above [1] or [2], wherein the conductive material is one or more metals selected from the group consisting of Al, Ag, Au, Cu, Sn, and Zn.

[4] The organic photovoltaic cell according to any one of above [1] to [3], wherein the conductive material is nanoparticles having a diameter of 100 nm or less.

[5] The organic photovoltaic cell according to any one of above [1] to [3], wherein the conductive material is fibrous particles.

[6] The organic photovoltaic cell according to any one of above [1] to [5], wherein the alkali metal salt is a metal salt of Li, Na, K, or Cs.

[7] The organic photovoltaic cell according to any one of above [1] to [5], wherein the alkaline earth metal salt is any one of a metal salt selected from the group consisting of Ca, Mg, Sr, and Ba.

[8] The organic photovoltaic cell according to any one of [1] to [7], wherein the alkali metal salt and the alkaline earth metal salt is any one of a metal salt selected from the group consisting of a chloride salt, a fluoride salt, a bromide salt, an acetate salt, an oxalate salt, and a carbonate salt.

[9] The organic photovoltaic cell according to any one of [1] to [8], wherein the alkali metal salt and the alkaline earth metal salt is a salt having a particle diameter of 100 nm or less.

[10] The organic photovoltaic cell according to any one of [1] to [9], wherein the active layer comprises a fullerene derivative.

[11] A method for manufacturing an organic photovoltaic cell that comprises a pair of electrodes of a first electrode and a second electrode, and an active layer placed between the pair of electrodes, the method comprising the steps of:
forming the active layer; and
applying a coating liquid comprising an alkali metal salt or an alkaline earth metal salt, a conductive material, and a solvent on the active layer, thereby forming either one of the electrodes.

[12] A method for manufacturing an organic photovoltaic cell that comprises a pair of electrodes of a first electrode and a second electrode, and an active layer placed between the pair of electrodes, the method comprising the steps of:
applying a coating liquid comprising an alkali metal salt or an alkaline earth metal salt and a solvent on the active layer, thereby forming a metal salt layer; and
forming a conductive material layer comprising a conductive material and a solvent on the metal salt layer.

### BRIEF DESCRIPTION OF DRAWINGS

FIG. 1 is a schematic cross-sectional view illustrating an organic photovoltaic cell according to a first embodiment.

FIG. 2 is a schematic cross-sectional view illustrating an organic photovoltaic cell according to a second embodiment.

### EXPLANATIONS OF LETTERS OR NUMERALS

10 Organic Photovoltaic Cell

20 Substrate

32 First Electrode

34 Second Electrode

34a Metal Salt Layer

34b Conductive Material Layer

40 Active Layer

### DESCRIPTION OF EMBODIMENTS

Hereinafter, the present invention is described in detail with reference to the drawings. In the following description, each drawing only schematically illustrates shapes, sizes, and locations of constituent elements in such a degree that the present invention can be understood. Therefore, the present invention is not particularly limited by this description. In addition, the same references may be assigned and illustrated to the same constituent and redundant description thereof may be omitted.

### First Embodiment

### <Organic Photovoltaic Cell>

An organic photovoltaic cell according to a first embodiment comprises a pair of electrodes of a first electrode and a second electrode; and an active layer placed between the pair of electrodes, in which either one of the pair of electrodes comprises an alkali metal salt or an alkaline earth metal salt, and a conductive material.

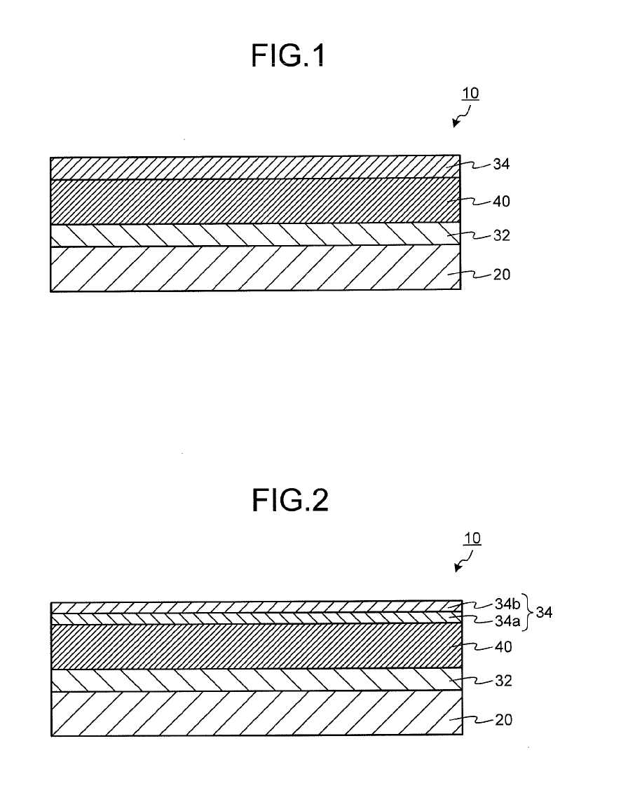

First, constitution of the organic photovoltaic cell is described with reference to FIG. 1.

FIG. 1 is a schematic cross-sectional view illustrating the organic photovoltaic cell according to the first embodiment.

As shown in FIG. 1, an organic photovoltaic cell 10 comprises a pair of electrodes of a first electrode 32 and a second electrode 34, and an active layer 40 placed between the pair of electrodes. These first electrode 32, active layer 40, and second electrode 34 are provided on a substrate 20.

Among the pair of electrodes, at least one electrode into which light is incident, that is, at least one of the electrodes is a transparent or semitransparent electrode that can transmit incident light (sunlight) having a wavelength required for power generation.

The organic photovoltaic cell comprises the pair of electrodes of the first electrode 32 and the second electrode 34, and the active layer 40 placed between the pair of electrodes. The polarity of the first electrode 32 and the second electrode 34 may be any preferable polarity corresponding to a cell structure. Although an example in which the first electrode 32 is an anode and the second electrode 34 is a cathode is described, it is also possible that the first electrode 32 is a cathode and the second electrode 34 is an anode.

The first electrode 32 and the second electrode 34 according to the first embodiment is constituted as electrodes comprising an alkali metal salt or an alkaline earth metal salt, and a conductive material as materials.

In this example, the second electrode 34 being a cathode is an electrode comprising the alkali metal salt or the alkaline earth metal salt, and the conductive material as the materials.

The conductive material being the material for the electrode may preferably be one or more metals selected from the group consisting of aluminum (Al), silver (Ag), gold (Au), copper (Cu), tin (Sn), and zinc (Zn).

This conductive material is preferably nanoparticles having a diameter of 100 nm or less. Here, the nanoparticle means a particle having a diameter of 100 nm or less. The nanoparticle preferably has a diameter of 50 nm or less from the viewpoint of making sintering temperature lower. In addition, the nanoparticle preferably has a diameter of 5 nm or more from the viewpoint of stability of the nanoparticle during a non-heating process at the time of storage or an applying step.

The conductive material is preferably fibrous particles. Here, the fibrous particle means a particle having an aspect ratio of 10 or more and 100000 or less. The aspect ratio is defined as a ratio of a fiber diameter to a fiber length. The aspect ratio of the fibrous particle is preferably 100 or more from the viewpoint of conductivity. The fibrous particle has a large amount of gap (void) inside of the agglomerate thereof. Consequently, the fibrous particles can uniformly be mixed with an alkali metal salt or an alkaline earth metal salt. A fiber diameter of the fibrous particle is preferably 100 nm or less from the viewpoint of promoting sintering in lower temperature.

The conductive material is preferably a mixture of the nanoparticles and the fibrous particles. In addition, the conductive material may be the fibrous particles as well as the nanoparticles.

The alkali metal salts comprised in the electrode may be preferably metal salts of lithium (Li), sodium (Na), potassium (K), or cesium (Cs).

The alkaline earth metal salts comprised in the electrode may be preferably any one of metal salts selected from the group consisting of calcium (Ca), magnesium (Mg), strontium (Sr), and barium (Ba).

Any of the alkali metal salt and the alkaline earth metal salt comprised in the electrode is preferably any one of metal salts selected from the group consisting of a chloride salt, a fluoride salt, a bromide salt, an acetate salt, an oxalate salt, and a carbonate salt.

The alkali metal salt and the alkaline earth metal salt are preferably a salt having a particle diameter of 100 nm or less.

The other electrode that faces the electrode according to the first embodiment comprising a alkali metal salt or an alkaline earth metal salt, and the foregoing conductive material as a material is described.

The transparent or semitransparent electrodes may be a conductive metal oxide film and a semitransparent thin metal film. Specifically, films made of conductive materials such as indium oxide, zinc oxide, tin oxide and indium-tin oxide (may referred to as ITO) and indium-zinc oxide that are mixture materials thereof; NESA; and films made of gold, platinum, silver, copper, and the like are used as the electrodes. Films of ITO, indium-zinc oxide, and tin oxide are preferable. Examples of methods for forming the electrode may include a vacuum evaporation method, a sputtering method, an ion plating method, and a plating method. As the electrode, an organic transparent conductive film such as polyaniline and a derivative thereof and polythiophene and a derivative thereof may be used.

As electrode materials for an opaque electrode, metals, conductive macromolecules, and the like can be used. Specific examples of the electrode material for the opaque electrode include metals such as lithium, sodium, potassium, rubidium, cesium, magnesium, calcium, strontium, barium, aluminum, scandium, vanadium, zinc, yttrium, indium, cerium, samarium, europium, terbium and ytterbium; and alloys made of two or more of these metals, or alloys made of one or more metals and one or more metals selected from the group consisting of gold, silver, platinum, copper, manganese, titanium, cobalt, nickel, tungsten and tin; graphite, intercalation graphite compound, polyaniline and a derivative thereof and polythiophene and a derivative thereof. Examples of the alloys include a magnesium-silver alloy, a magnesium-indium alloy, a magnesium-aluminum alloy, an indium-silver alloy, a lithium-aluminum alloy, a lithium-magnesium alloy, a lithium-indium ally, and a calcium-aluminum alloy.

The organic photovoltaic cell is usually formed on the substrate. More specifically, a layered structure comprising the first electrode 32, the active layer 40 that is provided on the first electrode 32, and the second electrode 34 provided on the active layer 40 is provided on the main surface of the substrate 20.

A material for the substrate 20 may be any material that is not chemically changed when the electrode is formed and a layer comprising an organic material is formed. Examples of the material for the substrate 20 may include glasses, plastics, macromolecular films, and silicon.

When the substrate 20 is opaque, that is, the substrate does not transmit incident light, the second electrode 34 that faces the first electrode 32 and is provided on the opposite side of the substrate (the electrode that is further from the substrate 20) is preferably a transparent electrode or a semitransparent electrode that can transmits necessary incident light.

The active layer 40 is placed between the first electrode 32 and the second electrode 34. The active layer 40 comprises an electron acceptor compound (an n-type semiconductor) and an electron donor compound (a p-type semiconductor) in a mixed manner. In this example the active layer is a bulk hetero type organic layer. The active layer 40 has an essential function for photovoltaic function that can generate charges (holes and electrons) using incident light energy.

As described above, the active layer 40 comprised in the organic photovoltaic cell 10 comprises the electron donor compound and the electron acceptor compound.

The electron donor compound and the electron acceptor compound are relatively determined by energy level of these compounds. Therefore, one compound can become either the electron donor compound or the electron acceptor compound.

Examples of the electron donor compounds may include pyrazoline derivatives, arylamine derivatives, stilbene derivatives, triphenyldiamine derivatives, oligothiophene and derivatives thereof, polyvinylcarbazole and derivatives thereof, polysilane and derivatives thereof, polysiloxane derivatives having aromatic amines in the main chain or side chains thereof, polyaniline and derivatives thereof, polythiophene and derivatives thereof, polypyrrole and derivatives thereof, polyphenylene vinylene and derivatives thereof, and polythienylene vinylene and derivatives thereof.

Examples of the electron acceptor compounds include oxadiazole derivatives, anthraquinodimethane and derivatives thereof, benzoquinone and derivatives thereof, naphthoquinone and derivatives thereof, anthraquinone and derivatives thereof, tetracyanoanthraquinodimethane and derivatives thereof, fluorenone derivatives, diphenyldicyanoethylene and derivatives thereof, diphenoquinone derivatives, metal complexes of 8-hydroxyquinoline and derivatives thereof, polyquinoline and derivatives thereof, polyquinoxaline and derivatives thereof, polyfluorene and derivatives thereof, fullerenes such as C₆₀ fullerene and derivatives thereof, phenanthrene derivatives such as bathocuproine, metal oxides such as titanium oxide, and carbon nanotubes. As the electron acceptor compounds, titanium oxide, carbon nanotubes, fullerenes, and fullerene derivatives are preferable, and fullerenes and fullerene derivatives are particularly preferable.

Examples of the fullerenes may include C₆₀ fullerene, C₇₀ fullerene, C₇₆ fullerene, C₇₈ fullerene, and C₈₄ fullerene.

Examples of the fullerene derivatives include derivatives of each C₆₀ fullerene, C₇₀ fullerene, C₇₆ fullerene, C₇₈ fullerene, and C₈₄ fullerene. Examples of specific structures of the fullerene derivatives may include the following structures.

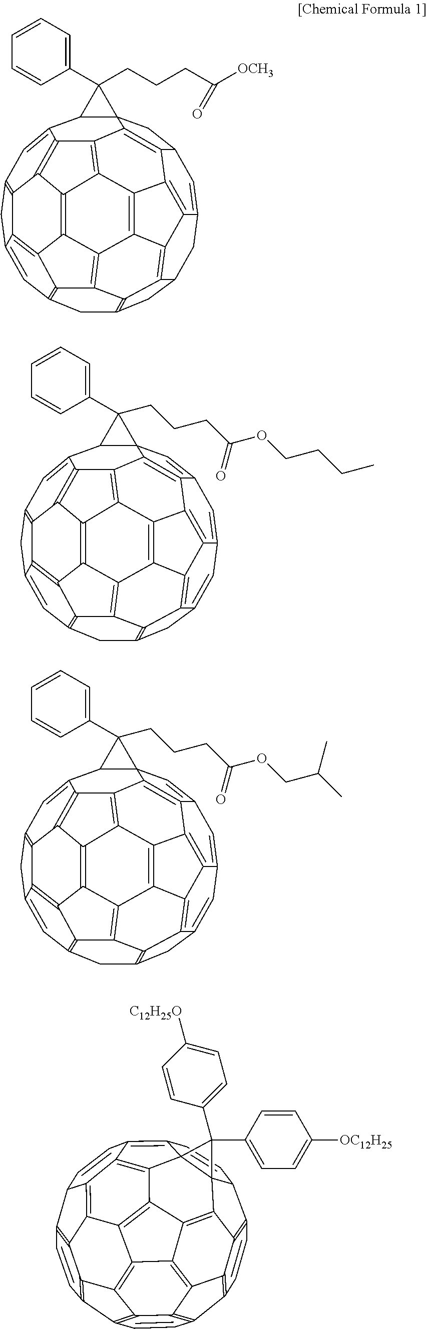

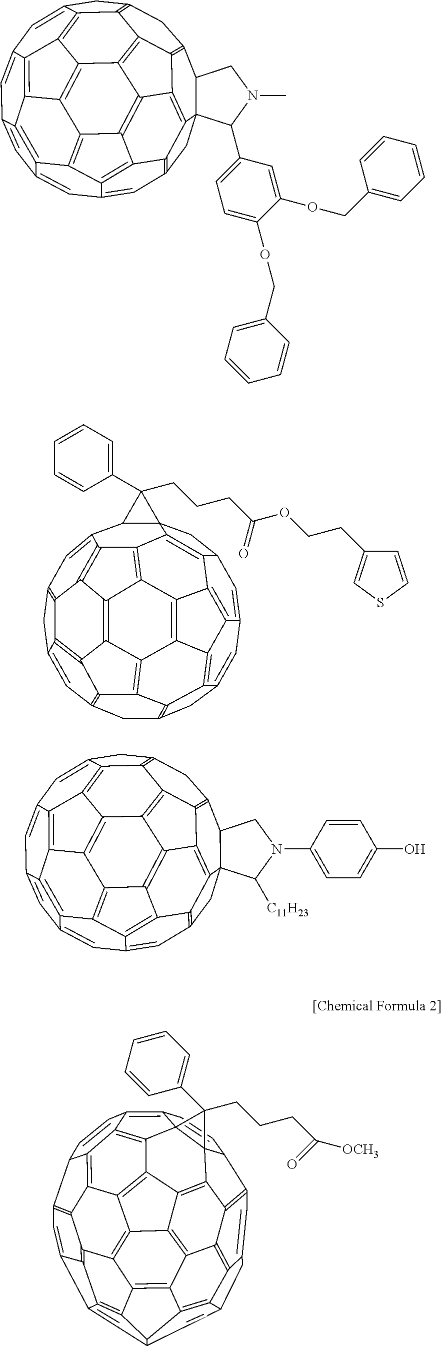

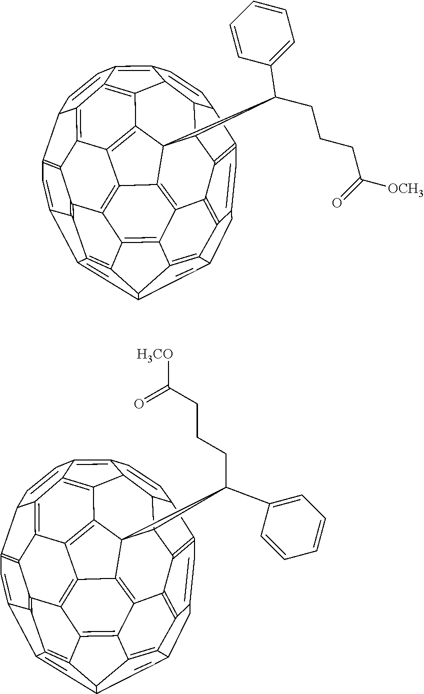

In addition, examples of the fullerene derivatives may include [6,6]-Phenyl C₆₁ butyric acid methyl ester (C₆₀PCBM), [6,6]-Phenyl C₇₁ butyric acid methyl ester (C₇₀PCMB), [6,6]-Phenyl C₈₅ butyric acid methyl ester (C₈₄PCBM), and [6,6]-Thienyl C₆₁ butyric acid methyl ester.

When the fullerene derivatives are used as the electron acceptor compounds, an amount of the fullerene derivative is preferably 10 parts by weight to 1000 parts by weight, and more preferably 20 parts by weight to 500 parts by weight per 100 parts by weight of the electron donor compound.

Usually, a thickness of the active layer is preferably 1 nm to 100 μm, more preferably 2 nm to 1000 nm, further preferably 5 nm to 500 nm, and particularly preferably 20 nm to 200 nm.

In the organic photovoltaic cell, an additional layer (an intermediate layer) other than the active layer 40 can be provided as a means for improving photovoltaic efficiency between at least one the electrode of the first electrode 32 and the second electrode 34, and the active layer. As examples of materials for the additional intermediate layer, a halide of an alkali metal and an alkaline-earth metal such as lithium fluoride and an oxide of the alkali metal and the alkaline-earth metal can be used. In addition, examples of materials may include fine particles of inorganic semiconductor such as titanium oxide, and PEDOT (poly-3,4-ethylenedioxythiophene).

Examples of the additional layer may include the charge transport layer that transports holes or electrons (a hole transport layer, an electron transport layer).

Any preferable material can be used for a material constituting the charge transport layer. When the charge transport layer is the electron transport layer, examples of the material may include 2,9-dimethyl-4,7-diphenyl-1,10-phenanthroline (BCP). When the charge transport layer is the hole transport layer, examples of the material may include PEDOT.

The additional intermediate layer that may be provided between the first electrode 32 and the second electrode 34, and the active layer 40 may be a buffer layer. Examples of materials used for the buffer layer may include a halide of an alkali metal and an alkaline-earth metal such as lithium fluoride and oxides such as titanium oxide. When an inorganic semiconductor is used, the inorganic semiconductor can be used in the form of fine particles.

In the foregoing example, the single layer active layer in which the active layer 40 is the bulk hetero type that is made by mixing the electron acceptor compound and the electron donor compound is described. However, the active layer 40 may be constituted by a plurality of layers. For example, the active layer may be a hetero-junction type in which the electron acceptor layer comprising the electron acceptor compound such as the fullerene derivative and an electron donor layer comprising the electron donor compound such as P3HT are joined.

Here, one example of layer constitution in which the organic photovoltaic cell can be formed.
a) Anode/Active layer/Cathode
b) Anode/Hole transport layer/Active layer/Cathode
c) Anode/Active layer/Electron transport layer/Cathode
d) Anode/Hole transport layer/Active layer/Electron transport layer/Cathode
e) Anode/Electron supplying layer/Electron acceptor layer/Cathode
f) Anode/Hole transport layer/Electron donor layer/Electron acceptor layer/Cathode
g) Anode/Electron donor layer/Electron acceptor layer/Electron transport layer/Cathode
h) Anode/Hole transport layer/Electron donor layer/Electron acceptor layer/Electron transport layer/Cathode
   (Here, the symbol “/” represents that layers sandwiching the symbol “/” are adjacently stacked each other).

The layer constitution may be either a form in which the anode is provided at the nearer side to the substrate or a form in which the cathode is provided at the nearer side to the substrate.

Each of the layers may be constituted by not only a single layer but also a layered body made of two or more layers.

In the organic photovoltaic cell, a amount of the electron acceptor compound in the bulk hetero type active layer comprising the electron acceptor compound and the electron donor compound is preferably 10 parts by weight to 1000 parts by weight, and more preferably 50 parts by weight to 500 parts be weight per 100 parts by weight of the electron donor compound.

### <Method for Manufacturing>

Subsequently, a method for manufacturing the organic photovoltaic cell according to the first embodiment is described with reference to FIG. 1.

The method for manufacturing an organic photovoltaic cell comprising a pair of electrodes of a first electrode and a second electrode; and an active layer placed between the pair of electrodes, the method comprises the steps of: forming the active layer; and applying a coating liquid comprising an alkali metal salt or an alkaline earth metal salt, a conductive material, and a solvent on the active layer, thereby forming either one of the electrodes.

First, the substrate 20 is prepared for manufacturing the organic photovoltaic cell 10. The substrate 20 is a planar substrate having two facing surfaces of main surfaces. For preparing the substrate 20, a substrate in which a conductive material thin film being possible to be a material for an electrode such as indium tin oxide is previously provided on one main surface of the substrate 20 may be prepared.

When the conductive material thin film is not provided on the substrate 20, the conductive material thin film is formed on one main surface of the substrate 20 by any preferable method. Subsequently, the conductive material thin film is patterned. The conductive material thin film is patterned by any preferable method such as a photolithography process and an etching process, thereby forming the first electrode 32.

Subsequently, the active layer 40 is formed in accordance with a common procedure on the entire surface of the substrate 10 on which the first electrode 32 is formed. The active layer 40 is formed by a coating method such as a spin coating method in which a coating liquid made by mixing a solvent and any preferable material for the active layer is applied.

Subsequently, the second electrode 34 is formed on the active layer 40. The second electrode 34 can be formed by a film forming method using a coating liquid, that is, a solution in this example.

As methods for forming the film, coating methods comprising a spin coating method, a casting method, a microgravure coating method, a gravure coating method, a bar coating method, a roll coating method, a wire-bar coating method, a dip coating method, a spray coating method, a screen printing method, a gravure printing method, a flexographic printing method, an offset printing method, an ink-jet printing method, a dispenser printing method, a nozzle coating method, and a capillary coating method can be used. Preferable methods comprises the spin coating method, the flexographic printing method, the gravure printing method, the ink-jet printing method, and the dispenser printing method.

Solvent used for these methods for forming the film that use the solution is not particularly limited as long as the solvent dissolves the foregoing material for the second electrode 34, that is, alkali metal salts or alkaline earth metal salts, and a conductive material.

Examples of such solvents may include alcohol solvents such as methanol, ethanol, 1-propanol, isopropyl alcohol, tert-butanol, ethylene glycol, propylene glycol, α-terpineol, ethyl carbitol acetate, butyl carbitol acetate, ethyl cellosolve, and butyl cellosolve; alkanes such as n-octane, n-decane, n-undecane, n-dodecane, and n-tetradecane.

Formation of the second electrode 34 is completed by drying the applied and formed layers in preferable conditions for the material and the solvent under any preferable atmosphere such as a nitrogen gas atmosphere.

The organic photovoltaic cell according to the first embodiment can be manufactured by performing the foregoing steps.

### Second Embodiment

### <Organic Photovoltaic Cell>

An organic photovoltaic cell according to a second embodiment comprises: a pair of electrodes of a first electrode and a second electrode; and an active layer placed between the pair of electrodes, in which either one of the pair of electrodes is constituted by stacking a metal salt layer comprising an alkali metal salt or an alkaline earth metal salt, and a conductive material layer comprising a conductive material, and the metal salt layer is joined with the active layer.

First, constitution of the organic photovoltaic cell is described with reference to FIG. 2. For the same constitution as the first embodiment as already described, the same references may be assigned and illustrated and detailed description may be omitted.

FIG. 2 is a schematic cross-sectional view illustrating an organic photovoltaic cell according to the second embodiment.

As shown in FIG. 2, the organic photovoltaic cell 10 comprises a pair of electrodes of the first electrode 32 and the second electrode 34, and the active layer 40 that is placed between the pair of electrodes.

These first electrode 32, active layer 40, and second electrode 34 are provided on the substrate 20.

Among the pair of electrodes, at least one electrode into which light is incident, that is, at least one of the electrodes is a transparent or semitransparent electrode that can transmits incident light (sunlight) having a wavelength required for power generation.

The organic photovoltaic cells comprise a pair of electrodes of the first electrode 32 and the second electrode 34, and the active layer 40 placed between the pair of electrodes. The polarity of the first electrode 32 and the second electrode 34 may be any preferable polarity corresponding to an element structure. It is also possible that the first electrode 32 is a cathode and the second electrode 34 is an anode.

The first electrode 32 or the second electrode 34 according to the second embodiment are constituted as an electrode made by stacking a metal salt layer 34a comprising an alkali metal salt or an alkaline earth metal salt as a material and a conductive material layer comprising a conductive material as a material.

In this embodiment, the second electrode 34 being a cathode is an electrode in which the metal salt layer 34a comprises the alkali metal salt or the alkaline earth metal salt as a material, and a conductive material layer 34b comprising the conductive material as a material are stacked. In addition, the metal salt layer 34a is joined with the active layer 40.

Constitution of the substrate 20, the other electrode, the active layer 40 and the additional layer is completely the same as the constitution in the first embodiment as already described. Therefore, detailed description is omitted.

Examples of the material for the conductive material layer 34b may include preferably one or more metals selected from the group consisting of aluminum (Al), silver (Ag), gold (Au), copper (Cu), tin (Sn), and zinc (Zn).

This conductive material is preferably nanoparticles having a diameter of 100 nm or less. The conductive material is preferably fibrous particles. The conductive material is preferably a mixture of the nanoparticles and the fibrous particles.

Examples of the alkali metal salt comprised in the metal salt layer 34a may include preferably a metal salt of lithium (Li), sodium (Na), potassium (K), and cesium (Cs).

Examples of the alkaline earth metal salt contained in the metal salt layer 34a may include preferably any one of metals selected from the group consisting of calcium (Ca), magnesium (Mg), strontium (Sr), and barium (Ba).

Any of the alkali metal salt and the alkaline earth metal salt comprised in the metal salt layer 34a is preferably any one of the salts selected from the group consisting of a chloride salt, a fluoride salt, a bromide salt, an acetate salt, an oxalate salt, and a carbonate salt.

The alkali metal salt and the alkaline earth metal salt are preferably a salt having a particle diameter of 100 nm or less.

### <Method for Manufacturing>

Subsequently, a method for manufacturing the organic photovoltaic cell according to the second embodiment is described with reference to FIG. 2. For the same steps as those of the first embodiment, detailed description of conditions and the like may be omitted.

A method for manufacturing an organic photovoltaic cell comprises the steps of: applying a coating liquid comprising an alkali metal salt or an alkaline earth metal salt and a solvent as materials on an active layer, thereby forming a metal salt layer; and forming a conductive material layer comprising a conductive material and a solvent on the metal salt layer.

In this embodiment, an example in which an electrode made by stacking the metal salt layer and the conductive material layer is a second electrode is described.

First, the substrate 20 is prepared for manufacturing the organic photovoltaic cell 10. The substrate 20 is a planar substrate having two facing surfaces of main surfaces. For preparing the substrate 20, a substrate in which a conductive material thin film being possible to be a material for an electrode such as indium tin oxide is previously provided on the one main surface of the substrate 20 may be prepared.

When the conductive material thin film is not provided on the substrate 20, the first electrode 32 is formed, as described above.

Subsequently, the active layer 40 is formed in accordance with a common procedure on the substrate 10 on which the first electrode 32 is formed. The active layer 40 can be formed by a coating method such as a spin coating method in which an coating liquid made by mixing a solvent and any preferable material for the active layer is applied, and the applied and formed layer is dried in preferable conditions for the material and the solvent under any preferable atmosphere such as a nitrogen gas atmosphere.

Subsequently, the second electrode 34 is formed on the active layer 40. The second electrode 34 can be formed by the same method for forming a film using a coating liquid, that is, a solution as the method for the active layer 40 described above.

As methods for forming the film, coating methods comprising a spin coating method, a casting method, a microgravure coating method, a gravure coating method, a bar coating method, a roll coating method, a wire-bar coating method, a dip coating method, a spray coating method, a screen printing method, a gravure printing method, a flexographic printing method, an offset printing method, an ink-jet printing method, a dispenser printing method, a nozzle coating method, and a capillary coating method may be used. Preferable methods comprise the spin coating method, the flexographic printing method, the gravure printing method, the ink-jet printing method, and the dispenser printing method.

Solvent used for these methods for forming the film that use the solution is not particularly limited as long as the solvent dissolves the above-described material for the second electrode 34, that is, alkali metal salts or alkaline earth metal salts, and a conductive material.

Examples of such solvents may include alcohol solvents such as methanol, ethanol, 1-propanol, isopropyl alcohol, tert-butanol, ethylene glycol, propylene glycol, α-terpineol, ethyl carbitol acetate, butyl carbitol acetate, ethyl cellosolve, and butyl cellosolve; alkanes such as n-octane, n-decane, n-undecane, n-dodecane, and n-tetradecane.

First, the metal salt layer 34a is formed on the formed active layer 40 by the coating method as already described. Specifically, a coating liquid made by mixing (dissolving) a selected alkali metal salt or an alkaline earth metal salt with a corresponding any preferable solvent is applied on the active layer 40. The metal salt layer 34a is formed by drying the applied and formed layers in preferable conditions for the material and the solvent under any preferable atmosphere such as a nitrogen gas atmosphere.

Subsequently, the conductive material layer 34b is formed on the formed metal salt layer 34a by the coating method as already described. Specifically, a coating liquid made by mixing (dissolving) a selected conductive material with a corresponding any preferable solvent is applied on the metal salt layer 34a. The conductive material layer 34b is formed by drying the applied and formed layers in preferable conditions for the material and the solvent under any preferable atmosphere such as a nitrogen gas atmosphere. As described above, formation of an electrode of the second electrode 34 made by stacking the metal salt layer 34a and the conductive material layer 34b is completed.

The organic photovoltaic cell according to the second embodiment can be manufactured by performing the foregoing steps.

According to the method for manufacturing the organic photovoltaic cell according to the first embodiment and the second embodiment described above, the electrodes are formed by the coating method in which heating at high temperature is not required. Consequently, the electrodes (or the electrode layer) can be formed by fairly easy processes without deterioration of a functional layer comprising organic compounds such as the active layer or without losing functions.

The organic photovoltaic cell manufactured by this method comprises the electrodes comprising the alkali metal salt or alkaline earth metal salt and the conductive material. Therefore, electric barrier at an interface between the electrode and the active layer in connection with the electrode becomes low. Consequently, the organic photovoltaic cell has excellent electrical characteristics.

### <Operation>

Here, an operation mechanism of the organic photovoltaic cell is simply described. Energy of incident light that transmits though the transparent or semitransparent electrode and is incident into the active layer is absorbed by the electron acceptor compound and/or the electron donor compound, and thereby exciters in which electrons and holes are combined are generated. When the generated exciters are moved and reached to a hetero-junction interface where the electron acceptor compound and the electron donor compound are joined, difference of each of HOMO energy and LUMO energy at the interface causes separation of electrons and holes and generates charges (electrons and holes) that can move independently. The organic photovoltaic cell can take out electric energy (electric current) to out of the cell by moving the generated charges to the electrodes (the cathode and the anode).

### <Application>

The organic photovoltaic cell manufactured by the method for manufacturing according to the present invention generates photovoltaic power between the electrodes by irradiating the first electrode and/or the second electrode that is or are transparent or semitransparent electrodes with light such as sunlight, and thereby can operate as an organic thin film solar cell. The organic thin film solar cell also can be used as an organic thin film solar cell module by stacking a plurality of organic thin film solar cells.

In addition, the organic photovoltaic cell manufactured by the method for manufacturing according to the present invention generates photocurrent by making light incident into cells through the electrodes that are transparent or semitransparent in a state in which voltage is applied to the first electrode and the second electrode or in a state in which voltage is not applied. Therefore, the organic photovoltaic cell manufactured by the method for manufacturing according to the present invention can be operated as an organic light sensor. The organic light sensor also can be used as an organic image sensor by integlating a plurality of organic light sensors.

### EXAMPLES

### Example 1

After washing a glass substrate (a first substrate) on which an ITO film was formed in a thickness of 150 nm by a spattering method with acetone, ultraviolet ozone cleaning treatment was performed for 15 minutes by an ultraviolet ozone irradiation device equipped with a low-pressure mercury vapor lamp (Type: UV-312, manufactured by Technovision, Inc.) to prepare an ITO electrode (a first electrode) having a clear surface. Subsequently, PEDOT (Trade name Baytron P AI4083, Lot. HCD07O109, manufactured by Starck) layer (a first charge transport layer) was formed by applying with a spin coating method on the glass substrate on which the ITO electrode was provided. Thereafter, the substrate was dried at 150° C. for 30 minutes in the atmosphere. After adding poly (3-hexyl thiophene) (P3HT) (Trade name: lisicon SP001, Lot. EF431002, manufactured by Merck.) as a conjugated macromolecular compound and PCBM (Trade Name: E100, Lot. 7B0168-A, manufactured by Frontier Carbon Corporation) as a fullerene derivative to an ortho-dichlorobenzene solvent so that P3HT is 1.5% by weight and PCBM is 1.2% by weight and stirring at 70° C. for 2 hours, the mixture is filtered with a filter having a pore diameter of 0.2 μm, thereby preparing a coating liquid. The coating liquid was applied on the PEDOT layer by the spin coating method. Thereafter, the applied layer was heat treated at 150° C. for 3 minutes in a nitrogen gas atmosphere. A film thickness of the active layer after heat treatment was about 100 nm.

A coating liquid 1 for electrode formation was prepared by adding 1% by weight of cesium carbonate to a silver nanopartcle dispersion (type SL-40, dispersion medium: water/isopropyl alcohol=70/30 (weight ratio), manufactured by Bando Chemical Industries, Ltd.) as a conductive material and dissolving the cesium carbonate by mixing with stirring. An electrode layer (a second electrode) was formed on the active layer by the spin coating method. Thereafter, the applied layer was heat treated at 130° C. for 10 minutes in a nitrogen gas atmosphere. A shape an organic thin film solar cell being the organic photovoltaic cell was a square of 2 mm×2 mm.

### <Evaluation>

For photovoltaic efficiency of the organic thin film solar cell, current and voltage were measured using a solar simulator (trade name YSS-80, manufactured by Yamashita Denso Corporation) by irradiating with light having irradiance of 100 mW/cm² through an AM 1.5 filter, and the photovoltaic efficiency was calculated. As a result, power generation by the prepared organic thin film solar cell was demonstrated.

### Example 2

A coating liquid 2 for electrode formation was prepared by adding 1% by weight of cesium carbonate to a solvent of water/isopropyl alcohol=70/30 (weight ratio) and dissolving the cesium carbonate by mixing with stirring. A cesium carbonate layer was formed on the active layer in a similar to Example 1 by the spin coating method using the coating liquid 2 for electrode formation. Thereafter, the applied layer was heat treated at 150° C. for 3 minutes in a nitrogen gas atmosphere. Subsequently, after forming a silver layer using the silver nanopartcle dispersion, the applied layer was heat treated at 130° C. for 10 minutes in a nitrogen gas atmosphere.

### <Evaluation>

For photovoltaic efficiency of the obtained organic thin film solar cell, current and voltage were measured using a solar simulator by irradiating with light having irradiance of 100 mW/cm² through an AM 1.5 filter, and the photovoltaic efficiency was calculated. As a result, power generation by the prepared organic thin film solar cell was demonstrated.

### INDUSTRIAL APPLICABILITY

The present invention is useful because the present invention provides the organic photovoltaic cell.

1. An organic photovoltaic cell comprising:
a pair of electrodes of a first electrode and a second electrode; and an active layer placed between the pair of electrodes, wherein
either one of the pair of electrodes comprises an alkali metal salt or an alkaline earth metal salt, and a conductive material.

2. An organic photovoltaic cell comprising:
a pair of electrodes of a first electrode and a second electrode; and an active layer placed between the pair of electrodes, wherein
either one of the pair of electrodes is constituted by stacking a metal salt layer comprising an alkali metal salt or an alkaline earth metal salt and a conductive material layer comprising a conductive material; and
the metal salt layer is joined with the active layer.

3. The organic photovoltaic cell according to claim 1, wherein the conductive material is one or more metals selected from the group consisting of Al, Ag, Au, Cu, Sn, and Zn.

4. The organic photovoltaic cell according to claim 1, wherein the conductive material is nanoparticles having a diameter of 100 nm or less.

5. The organic photovoltaic cell according to claim 1, wherein the conductive material is fibrous particles.

6. The organic photovoltaic cell according to claim 1, wherein the alkali metal salt is a metal salt of Li, Na, K, or Cs.

7. The organic photovoltaic cell according to claim 1, wherein the alkaline earth metal salt is any one of a metal salt selected from the group consisting of Ca, Mg, Sr, and Ba.

8. The organic photovoltaic cell according to claim 1, wherein the alkali metal salt and the alkaline earth metal salt is any one of a metal salt selected from the group consisting of a chloride salt, a fluoride salt, a bromide salt, an acetate salt, an oxalate salt, and a carbonate salt.

9. The organic photovoltaic cell according to claim 1, wherein the alkali metal salt and the alkaline earth metal salt is a salt having a particle diameter of 100 nm or less.

10. The organic photovoltaic cell according to claim 1, wherein the active layer comprises a fullerene derivative.

11. A method for manufacturing an organic photovoltaic cell that comprises a pair of electrodes of a first electrode and a second electrode, and an active layer placed between the pair of electrodes, the method comprising the steps of:
forming the active layer; and
applying a coating liquid comprising an alkali metal salt or an alkaline earth metal salt, a conductive material, and a solvent on the active layer, thereby forming either one of the electrodes.

12. A method for manufacturing an organic photovoltaic cell that comprises a pair of electrodes of a first electrode and a second electrode, and an active layer placed between the pair of electrodes, the method comprising the steps of:
applying a coating liquid comprising an alkali metal salt or an alkaline earth metal salt and a solvent on the active layer, threby forming a metal salt layer; and
forming a conductive material layer comprising a conductive material and a solvent on the metal salt layer.
